(19) United States
(12) Patent Application Publication
(10) Pub. No.: US 2017/0372877 A1
(43) Pub. Date: Dec. 28, 2017

(54) SUPPORT APPARATUS FOR PLASMA ADJUSTMENT, METHOD FOR ADJUSTING PLASMA, AND STORAGE MEDIUM

(71) Applicant: TOKYO ELECTRON LIMITED, Tokyo (JP)

(72) Inventors: Takafumi NOGAMI, Nirasaki City (JP); Makoto IGARASHI, Nirasaki City (JP)

(21) Appl. No.: 15/630,365

(22) Filed: Jun. 22, 2017

(30) Foreign Application Priority Data
Jun. 23, 2016 (JP) 2016-124686

(51) Int. Cl. H01J 37/32; H01L 21/67; H01L 21/687

(52) U.S. Cl. CPC H01J 37/32935; H01L 21/68714; H01L 21/67253; H01J 37/32201; H01J 37/32926; H01J 37/32715; H01J 2237/332

(57) ABSTRACT

A support apparatus for plasma adjustment includes a storage part storing index value estimation data including data defining an amount of change in an index value between adjustment positions for each of the adjustment parts, the index value corresponding to electron density of plasma, an input part for inputting a measurement result of the index value obtained when plasma is generated and the adjustment positions of the adjustment parts, and a data processing part configured to estimate the index value for each of adjustment positions of the adjustment parts based on input items input to the input part and the estimation data and configured to select proper combinations of the adjustment positions of the adjustment parts based on combinations of the adjustment positions of the adjustment parts and estimated values of a plurality of index values in the circumferential direction corresponding to the respective combinations.

### CROSS-REFERENCE TO RELATED APPLICATION

This application claims the benefit of Japanese Patent Application No. 2016-124686, filed on Jun. 23, 2016, in the Japan Patent Office, the disclosure of which is incorporated herein in its entirety by reference.

### TECHNICAL FIELD

The present disclosure relates to a technique for processing a substrate with plasma using a processing gas plasmarized by a microwave.

### BACKGROUND

As one process of manufacturing a semiconductor device, there is plasma treatment for performing a film forming process, an etching process, a sputtering process or the like with plasma. In addition, an apparatus using a microwave is known as an apparatus for performing plasma treatment. This apparatus includes a coaxial waveguide arranged vertically in the central portion of the upper part of a processing container, and a laminated body including a disc-shaped retarding plate, a slot antenna having a plurality of slots, and a dielectric plate which are laminated in this order from the top, in which the lower end of the coaxial waveguide is connected to the slot antenna. A microwave propagates from a microwave generator through the coaxial waveguide to the retarding plate, spreads in a radial direction, and is radiated from the slots of the slot antenna to the dielectric plate to generate an electric field in the lower side of the dielectric plate.

The coaxial waveguide includes an inner conductor and an outer conductor, which are manufactured separately and are assembled such that the radial centers of both conductors coincide with each other. Then, a plasma processing apparatus is assembled with the center of the inner conductor coinciding with the center of the slot antenna. However, it is difficult to avoid a deviation by a very small amount (e.g., about 0.05 mm) between the center of the inner conductor and the center of the outer conductor after maintenance or the like. Even such a positional deviation may bias an electric field distribution, which is a factor of deterioration of the in-plane uniformity of plasma treatment on a substrate.

In this connection, there has been proposed a technique for ensuring the uniformity of generated plasma in the circumferential direction by adjusting the balance of an electric field in the circumferential direction by changing a distance between each of six stub members extending from an outer conductor to an inner conductor side of a coaxial waveguide, which are arranged at equal intervals along the circumferential direction, and the inner peripheral surface of the inner conductor. There has also been proposed a technique for correcting a deviation of an electric field distribution by adjusting an electric field intensity in a microwave transmission window by adjusting the length of a waveguide, which is a stub above slots arranged at the outermost periphery of a slot antenna so as to overlap with the slots, by means of a movable member.

However, in order to adjust the electric field intensity distribution by the stub, that is, to adjust plasma (more specifically, to adjust the electron density of the plasma), an experienced operator has to derive the optimal combination of adjustment positions in consideration of an adjustment procedure according to situations. Therefore, a long-term education is required before a worker acquires an adjustment technique. Further, even for a worker who has learned the adjustment technique, since a trial and error occurs in the adjustment work itself, a big burden is imposed on the worker and there is a possibility that a variation in adjustment will occur for each worker.

### SUMMARY

Some embodiments of the present disclosure provide a technique for allowing an adjustment part to easily perform plasma adjustment in a plasma processing apparatus using a microwave.

According to the embodiments of the present disclosure, there is provided a support apparatus for plasma adjustment, which is used in a plasma processing apparatus in which a processing gas is plasmarized by a microwave propagated from a coaxial waveguide located above a central portion of a substrate placed in a processing container into the processing container via a flat slot antenna and a dielectric plate, plasma treatment is performed on the substrate, and a plurality of adjustment parts for adjusting an electric field distribution of the microwave installed along a circumferential direction of the processing container, including: a storage part that stores index value estimation data including data defining an amount of change in an index value between adjustment positions for each of the adjustment parts, the index value corresponding to electron density of plasma at a plurality of specific positions separated by a predetermined distance from a central axis of the coaxial waveguide and located along the circumferential direction when viewed from the top; an input part for inputting a measurement result of the index value obtained when the plasma is generated and the adjustment positions of the adjustment parts; and a data processing part configured to estimate the index value for each of adjustment positions of the adjustment parts based on input items input to the input part and the estimation data and configured to select proper combinations of the adjustment positions of the adjustment parts based on combinations of the adjustment positions of the adjustment parts and estimated values of a plurality of index values in the circumferential direction corresponding to the respective combinations.

According to the embodiments of the present disclosure, there is provided a method for adjusting plasma of a plasma processing apparatus in which a processing gas is plasmarized by a microwave propagated from a coaxial waveguide located above the central portion of a substrate placed in a processing container into the processing container via a flat slot antenna and a dielectric plate, plasma treatment is performed on the substrate, and a plurality of adjustment parts for adjusting an electric field distribution of the microwave installed along the circumferential direction of the processing container, including: generating plasma using the plasma processing apparatus and measuring an index value corresponding to the electron density of plasma at a plurality of specific positions separated by a predetermined distance from a central axis of the coaxial waveguide and located along the circumferential direction; inputting a measurement result of the index value and adjustment positions of the adjustment parts to an input part; reading index value estimation data defining the amount of change in the index value between the adjustment positions of the adjustment parts for each of the adjustment parts from a storage part; and estimating the index value for each of the adjustment positions of the adjustment parts based on the read estimation data and input items input to the input part and selecting proper combinations of the adjustment positions of the adjustment parts based on combinations of the adjustment positions of the adjustment parts and the estimated values of the plurality of index values in the circumferential direction corresponding to the respective combinations.

According to the embodiments of the present disclosure, there is provided a non-transitory computer-readable storage medium storing software used for the support apparatus for plasma adjustment of the support apparatus described above, wherein the software is configured to execute a function of the data processing part.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view showing an example of a plasma processing apparatus in which plasma is to be adjusted, according to the present disclosure.

FIG. 2 is an enlarged sectional view showing a stub serving as an adjustment part for plasma adjustment in the plasma processing apparatus and its surroundings.

FIG. 3 is a cross-sectional view showing a part corresponding to FIG. 2.

FIG. 4 is an explanatory view for explaining adjustment positions of stubs.

FIGS. 5A and 5B are schematic views showing a film thickness distribution on a substrate in a case of not using a stub and a case of using a stub, respectively.

FIG. 6 is an explanatory view schematically showing an outline of an embodiment of a plasma adjusting method of the present disclosure.

FIG. 7 is an explanatory view schematically showing an outline of an embodiment of a plasma adjusting method of the present disclosure.

FIG. 8 is an explanatory view visually showing how to obtain the optimal combination of positions of stubs.

FIG. 9 is a configuration diagram showing a support apparatus for plasma adjustment according to the present disclosure.

FIG. 10 is a graph showing measured values of film thickness and refractive index at specific positions on a wafer obtained by performing plasma treatment with various set stub positions.

FIG. 11 is a graph showing an example of estimation data for estimating a film thickness at a specific position on a wafer corresponding to the position of a stub.

FIG. 12 is a graph showing an example of estimation data for estimating a refractive index of a film at a specific position on a wafer corresponding to the position of a stub.

FIG. 13 is a graph showing an example of estimation data for estimating a film thickness at a specific position on a wafer corresponding to the position of a stub.

FIG. 14 is a graph showing an example of estimation data for estimating a refractive index of a film at a specific position on a wafer corresponding to the position of a stub.

FIG. 15 is a flowchart showing a specific example of an embodiment of a plasma adjusting method of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### [Description on Overall Configuration of Plasma Processing Apparatus]

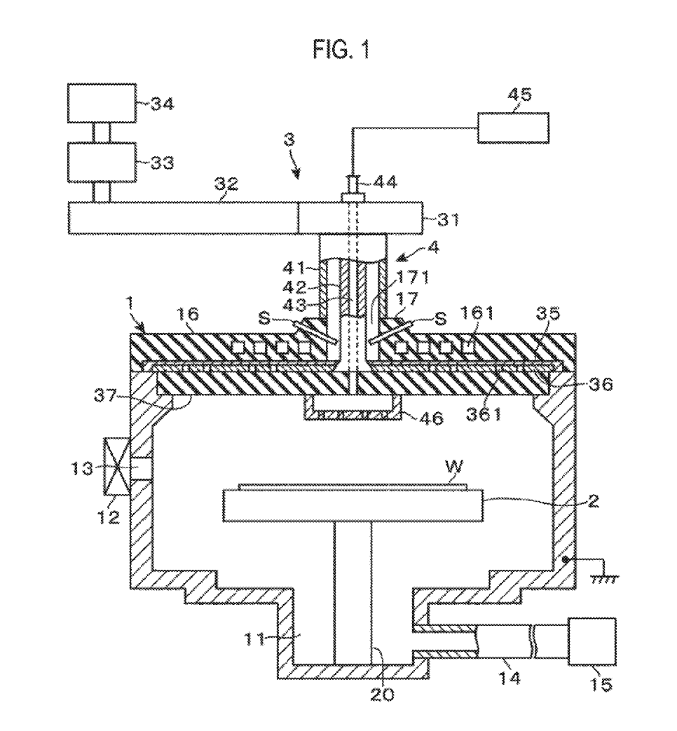

Prior to description on embodiments of a plasma adjustment assisting apparatus and a plasma adjusting method according to the present disclosure, a plasma processing apparatus to which the present disclosure is applied will be briefly described. As shown in FIG. 1, the plasma processing apparatus includes a processing container 1 which is a vacuum chamber having a recess 11 formed in the center of the bottom of the chamber, and a mounting table 2 made of, e.g., ceramics and supported on a supporting rod 20 extending from the bottom of the recess 11. The mounting table 2 has a heating mechanism formed therein. On the side surface of the processing container 1 is formed a transfer port 13 for a semiconductor wafer (hereinafter simply referred to as a wafer) which is a substrate. The transfer port 13 is opened and closed by a gate valve 12. A proximal end side of an exhaust pipe 14 is connected to the side surface of the recess 11 of the processing container 1, while a distal end side is connected with a vacuum exhaust mechanism 15.

The plasma processing apparatus is provided with a microwave introduction mechanism 3 including a coaxial waveguide 4 having a circular section which is vertically arranged in the center on the upper side of the processing container 1, and a laterally extending rectangular waveguide 32 having one end connected to the upper end portion of the coaxial waveguide 4 via a mode converter 31. A microwave generator 34 is connected to the other end side of the rectangular waveguide 32 via a matching device 33.

A conductive ceiling plate 16 is installed on the upper surface of the processing container 1, the center of the ceiling plate 16 is formed as a projection 17 projecting upward, and an opening 171 is formed in the projection 17. A flow path 161 through which a cooling medium flows is formed inside the ceiling plate 16. The coaxial waveguide 4 is composed of a cylindrical outer conductor 41 and a rod-shaped inner conductor 42 having a circular section and arranged coaxially with the cylindrical outer conductor 41 with a gap formed between the outer conductor 41 and the inner conductor 42. The outer conductor 41 is connected to the edge portion of the opening 171 of the ceiling plate 16.

On the lower side of the ceiling plate 16 are laminated a retarding plate 35, a slot antenna 36 and a dielectric plate 37 which is a microwave transmission window in this order from the top. The retarding plate 35 and the dielectric plate 37 are each formed in a circular shape by a dielectric material such as quartz, alumina or the like. The slot antenna 36 is formed of, e.g., a copper plate or an aluminum plate whose surface is plated with gold or silver. For example, the slot antenna 36 has slit pairs arranged in the inner peripheral side and outer peripheral side of the circumferential direction, each pair including two slits, which are slots 361, disposed in a T shape.

The inner conductor 42 of the coaxial waveguide 4 penetrates through the retarding plate 35 and is connected to the center portion of the slot antenna 36. A gas flow path 43 is formed in the center portion of the inner conductor 42 and has one end connected to a gas supply pipe 44 via the outer surface of the mode converter 31. A gas supply source 45 is connected to the proximal end of the gas supply pipe 44. Examples of gases used for plasma treatment may include an argon gas for plasma generation, an oxygen gas for oxidation treatment, a processing gas such as a precursor gas for CVD, a nitrogen gas for purging, etc. Gas supply systems for these gases are represented by the gas supply pipe 44 and the gas supply source 45. The distal end of the gas flow path 43 is opened to the bottom of the dielectric plate 37 through the dielectric plate 37. On the bottom of the dielectric plate 37 is installed a gas shower head 46 forming a flat cylindrical gas supply part so as to surround the opening of the gas flow path 43. A number of gas discharge ports are formed in the bottom of the gas shower head 46.

In the above-described plasma processing apparatus, a wafer W as a substrate is loaded into the processing container 1 via the transfer port 13 and is placed on the mounting table 2. Then, for example, a precursor gas for CVD and an argon gas are introduced from the gas supply source 45 into the processing container 1 via the shower head 46 and, subsequently, a microwave of, e.g., 2.45 GHz generated in the microwave generator 34 is introduced into the processing container 1. The microwave propagates in a TE mode in the rectangular waveguide 32, is converted into a TEM mode in the mode converter 31, and propagates through the coaxial waveguide 4. Specifically, the microwave propagates through the gap between the outer conductor 41 and the inner conductor 42 of the coaxial waveguide 4 and propagates between the inner peripheral surface of the opening portion of the ceiling plate 16 and the inner conductor 42. Further, the microwave propagates through the retarding plate 35 in the radial direction and is radiated onto the dielectric plate 37 through the slot 361 of the slot antenna 36 to generate an electric field immediately under the dielectric plate 37. This electric field plasmarizes (excites) the processing gas in the processing container 1 to generate plasma. This generated plasma is used to subject the wafer W to plasma treatment such as a film forming process.

[Description on Stub which is Adjusting Part for Adjusting Plasma]

The above-described plasma processing apparatus includes stubs S, which are adjustment parts for adjusting plasma, in particular, for adjusting the electron density of the plasma by adjusting an electric field distribution caused by the microwave. A plurality of stubs S is arranged circumferentially around the inner conductor 42 of the coaxial waveguide 4 with a space from the inner conductor 42. In the following embodiments, the number of stubs S is 6, but this number of 6 is just an example for explanation. Each stub S is made of, e.g., aluminum or the like and is configured as a rod-like body forming a diameter extension part 51 in which a portion closer to one end is larger in diameter than a portion closer to the other end. A threaded portion is formed on the outer peripheral surface of the diameter extension part 51.

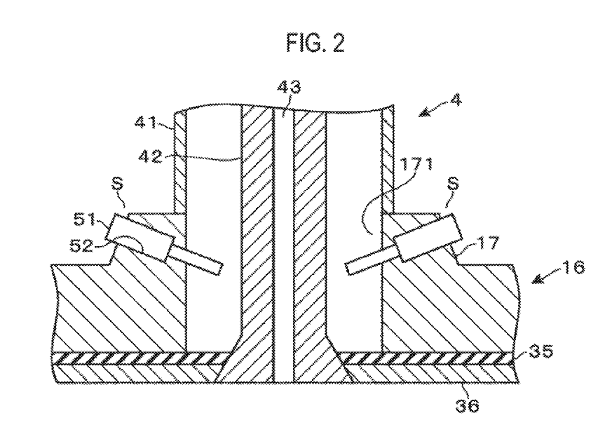

As shown in FIGS. 1 and 2, in the projection 17 at the center portion of the ceiling plate 16, six mounting holes 52, which are through-holes extending laterally and downwardly toward the inner conductor 42, are circumferentially formed at equal intervals. A threaded portion is formed in each of the mounting holes 52. Each of the six stubs S is inserted from the outside of the corresponding mounting hole 52 and is mounted in the projection in a state where the threaded portion of the stub S and the threaded portion of the mounting hole 52 are engaged. Thus, the x stubs S are arranged at equal intervals along the circumferential direction of the processing container 1 (the circumferential direction of the inner conductor 42).

When no stub S is present and the center of the outer conductor 41 and the center of the inner conductor 42 are perfectly aligned with each other, the lines of electric three extending from the inner conductor 42 toward the outer conductor 41 are uniformly distributed in the circumferential direction. However, if the two centers are misaligned, the uniformity of the electric force lines in the circumferential direction may collapse. Accordingly, when the stub S is projected from the inner peripheral surface of the opening 171 of the ceiling plate 16, portions each having a distance from the outer peripheral surface of the inner conductor 42 shorter than a distance between the outer peripheral surface of the inner conductor 42 and the other portion facing the outer peripheral surface is formed and the electric force lines are accordingly concentrated on these portions. Therefore, by adjusting the amount of projection of each stub S from the inner peripheral surface of the opening 171, it is possible to correct the collapse of the uniformity of the electric force lines in the circumferential direction. That is, the stub S can adjust the electron density of plasma by adjusting the electric field distribution formed by the microwave.

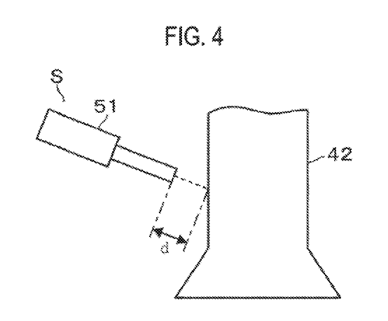

Regarding the adjustment of the aforementioned projection amount of the stub S, plural kinds of stubs S having different lengths are prepared for each of the six mounting holes 52 and, by screwing the stubs S with different lengths into the mounting holes 52, respectively, the aforementioned protrusion amount of the stub S is determined corresponding to the length. For the plural kinds of stubs S having different lengths, in the following description, for the sake of convenience, it is assumed that stubs S of 19 different lengths are prepared for each of the six mounting holes 52, but is indeed not limited thereto. Adjusting the aforementioned projection amount of the stub S is equivalent to adjusting a distance d from the center of the distal end of the stub S to the ouster peripheral surface of the inner conductor 42 in the axial direction of the stub S as shown in FIG. 4.

Therefore, if the kind of stub S is specified by a distance d, 19 types of stubs S having different distance d from one another are prepared. By selecting the stub S from the prepared 19 kinds of stubs S having different distances d, the position of the stub S, specifically, the position of the distal end of the stub S, can be adjusted. For example, if a stub S of a distance d of 1 mm is selected, it means that the position of the stub S is set to 1 mm. The allocation of the positions of the 19 kinds of stubs S is made to a position (distance d) selected from a range of d between 1 mm and 11 mm, for example. Therefore, stubs S such as 1 mm stub S, 1.5 mm stub S, 2 mm stub S, 2.5 mm stub S, 3 mm stub S and so on are prepared.

For example, when d is 11 mm or more, since the stub S is accommodated outside the inner peripheral surface of the opening 171, this is equivalent o a state where no stub S is present. Even in this case, a member for closing the mounting hole 52 is screwed into the mounting hole 52, but in the description of the embodiment, the state in this case is expressed as a state without a stub, that is, “no stub”.

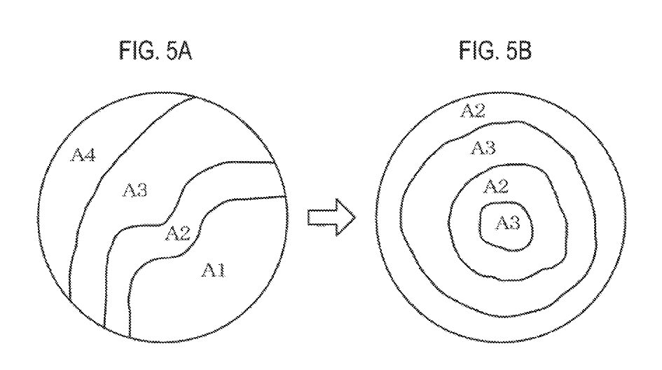

By adjusting the position of the stub S, in this example, by selecting the stub S specifying the distance d, the plasma density can be adjusted as described above. Therefore, it is possible to adjust an index corresponding to the plasma density, for example, a thickness of a thin film on the wafer W formed by plasma treatment. FIGS. 5A and 5B schematically show states where a film thickness distribution on the wafer W is adjusted by using a stub S. it is assumed in this figure that the film thickness increases in the order of A1<A2<A3<A4. FIG. 5A corresponds to a case where a film forming process, which is plasma treatment, is performed without using a stub S, showing that the film thickness gradually increases toward one of the left and right directions. On the other hand, FIG. 5B corresponds to a case where plasma treatment is performed using a stub S, showing that the film thickness uniformity in the circumferential direction is good, that is, the film thickness distribution is concentric. In a semiconductor process, it is considered that it is desirable to make plasma treatment uniform in the circumferential direction of the wafer W from the viewpoint of tuning of a semiconductor manufacturing apparatus. For this reason, there is a request to form the film thickness distribution as shown in FIG. 5B. In addition, since a difference in thickness of a film formed on the wafer can be reduced, the uniformity of the in-plane of the wafer W can also be improved.

### [Description on Embodiment of Plasma Adjustment Method of the Present Disclosure]

Next, an outline of an embodiment of the plasma adjusting method of the present disclosure using the stub S will be described. In assembling the apparatus at the time of starting up the apparatus or after maintenance, the coaxial waveguide 4 is assembled using the outer conductor 41 and the inner conductor 42; however, it is difficult to accurately align the centers of the outer conductor 41 and the inner conductor 42. The goal of the present embodiment is to grasp the position of each stub S which can compensate for the deviation in the uniformity of the plasma density (the electron density of plasma) in the circumferential direction of the wafer W due to the deviation of the centers between the outer conductor 41 and the inner conductor 42, that is, can ensure the uniformity of plasma treatment in the circumferential direction of the wafer W.

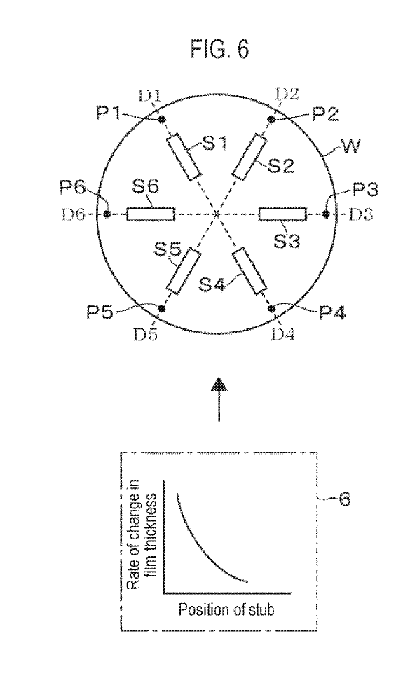

FIG. 6 is a view schematically showing the present embodiment, in which film thickness estimation data 6 defining the relationship between the position (the above-described distance d) of a stub S and the rate of change in film thickness at a position distant (e.g., by 145 mm) from the center of the wafer W for each of six mounting positions (mounting holes 52) are prepared. The “film thickness” used herein refers to the thickness of a film formed on the wafer W by setting six stubs S at certain positions (including “no stub”) and performing a film forming process, which is plasma treatment, on the wafer W.

FIG. 6 shows the positional relationship in the circumferential direction of the wafer W between the wafer W and the stubs S, in which the six stubs S are denoted by symbols S1 to S6, respectively. In the following description, a symbol S is used to explain the stubs in a comprehensive manner and symbols S1 to S6 are used to designate individual stubs. In FIG. 6, positions P1 to P6 are positions which are distant by, e.g., 145 mm from the center of the wafer W and which lie on lines connecting the centers in the width direction of the six stubs S1 to S6 to the center of the wafer W are denoted by P1 to P6, respectively. Since the center of the wafer W is arranged to align with the center of the coaxial waveguide 4, P1 to P6 denote six specific positions which lie along the circumferential direction and are distant by a preset distance of 145 mm from the central axis of the coaxial waveguide 4 when viewed from the top.

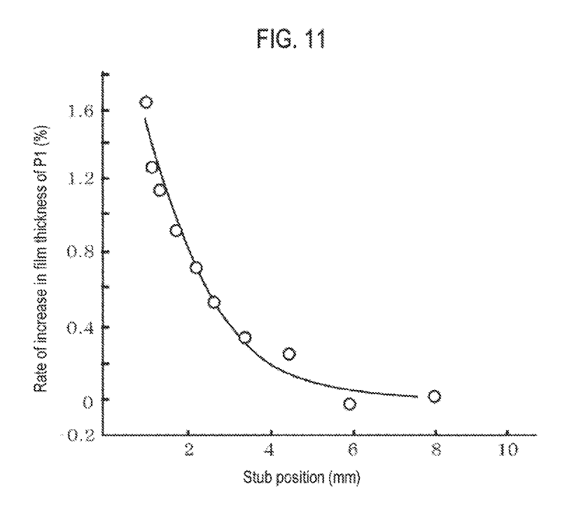

Returning to the film thickness estimation data 6, for example, the data 6 in the stub S1 in the film thickness estimation data 6 prepared for each of the mounting hole 52 of the stubs S, that is, prepared for each of the stubs S1 to S6, will be described. As shown in FIG. 11 to be described later, when the stub S1 is set at a certain position selected from the 19 positions described above, the data 6 represent how much the film thickness of P1 at that time is larger (or smaller) than the film thickness of P1 when the stub S1 is set as no stub. That is, the data 6 are represented, e.g., as a characteristic curve which shows that the rate of change in film thickness increases with the decrease in the aforementioned distance d (see FIG. 4) corresponding to the position of the stub S1, since they define the rate of change in film thickness of each of the 19 positions of stubs S1 with respect to the film thickness of P1 at no stub as the reference position. For example, in the film thickness estimation data 6, assuming that the rate of change in film thickness is 0.8% when the position of the stub S1 is 7 mm. and that the film thickness of P1 is 1,000 Å when the stub S1 is “no stub”, the film thickness of P1 is 1008 Å when the stub S1 is set to 7 mm.

Therefore, it can be said that the film thickness estimation data 6 define the amount of change in film thickness between the positions in the stub S1 using the film thickness when the stub S1 is set to be the reference position. The film thickness estimation data 6 can also be referred to as sensitivity data for the change in film thickness depending on the position of the stub S1. For example, assuming that the film thickness of P1 is measured with the stub S1 set to 3 mm, it is possible to estimate the film thickness of P1 when the stub S1 is set to 7 mm. The foregoing description is focused on only the relationship between the position of the stub S1 and the film thickness of P1 which is a position on the above-mentioned line passing through the stub S1, However, in reality, the position of the stub S1 affects the film thicknesses of P6 and P2 positioned on lines respectively connecting other stubs S6 and S2 adjacent to the stub S1 and the center of the wafer W. In other words, the film thickness of P1 is also affected by the positions of the other stubs S2 to S6. The influence becomes smaller as a stub S is located farther from the stub S1.

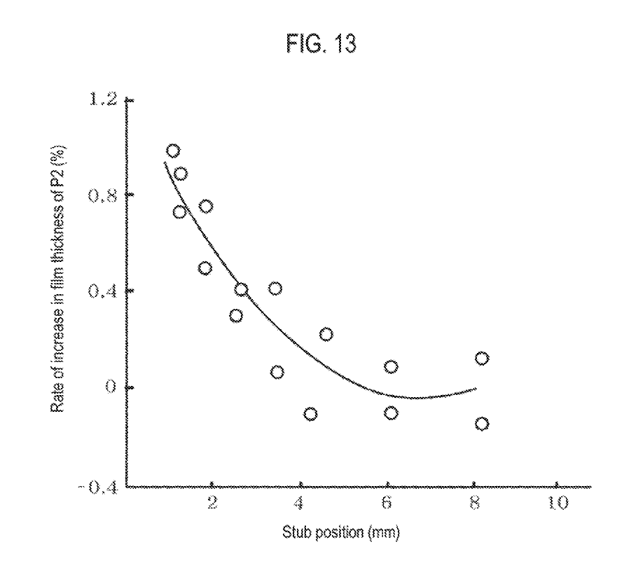

Therefore, when the film thickness of P1 needs to be accurately estimated in a state where each of the stubs S1 to S6 is set to a certain position, it is preferable to prepare the above-mentioned film thickness data 6 defining the relationship between the positions of the stubs S2 to S6 and the film thickness of P1 in addition to the film thickness estimation data 6 defining the relationship between the stub S1 and the film thickness of P1. In this case, in order to estimate the change in the film thickness of P1 depending on the position of the stub S2, the horizontal axis represents the position of the stub S2 and the vertical axis represents the rate of change in the film thickness of P1 when the stub S2 is set to each position with respect to the film thickness of P1 when the stub S2 is set to no stub. The same is true of the other stubs S3 to S6. For example, data showing the effect of the position of the stub S1 on the film thickness at the position P2 positioned on the line passing through the stub S2 adjacent to the stub S1 is shown in FIG. 13 to be described later.

As a result, when each of the stubs S1 to S6 is set to a certain position and the film thickness of P1 is measured to obtain a measured value, the film thickness of P1 can be estimated for any of combinations of the positions of the stubs S1 to S6. In this case, the film thickness of P1 corresponds to a value obtained by adding the amount of change in film thickness according to the position of the stub S1, the amount of change in film thickness according to the position of the stub S2 and the amount of change in film thickness according to each of the positions of the remaining stubs S3 to S6, to the obtained film thickness measured value. For example, for calculation of the amount of change in film thickness of P1 when the stub S1 is set to a certain position, the film thickness D₀1 when the stub S1 is no stub is obtained based on the film thickness measured value, the position of the stub S1 at the time of film thickness measurement, and the film thickness estimation data 6 defining the relationship between the position of the stub S1 and the amount of change in film thickness of P1. Then, the amount of change in film thickness of P1 is obtained based on the film thickness D₀1, the position of the stub S1 for which film thickness is to be estimated, and the film thickness estimation data 6.

For example, assuming that the position of the stub S1 at the time of measuring the film thickness is 4 mm and the measured value of the film thickness of P1 is 1,002 Å, since a value of the vertical axis when a value of the horizontal axis is 4 mm is 0.2% (this value may not be exact but is used for convenience of description) which is the rate of increase in film thickness at 4 mm with respect to the film thickness at no stub, the film thickness D₀1 of the stub S1 at no stub is 1,000 Å. Then, since the position of the stub S1 for which the film thickness is to be estimated is 2 mm and the value of the vertical axis at this time is 0.6% (this value may not be exact but is used for convenience of description), the rate of increase in the film thickness of P1 when the position of the stub S1 is 2 mm is 6 Å for the film thickness D₀1 (1,000 Å). Therefore, considering only the influence of the stub S1, an estimated value of the film thickness of P becomes 1,006 Å, which is larger by 4 Å than 1,002 Å which is the measured value of the film thickness.

Similarly, since the rate of increase in the film thickness of P1 at the position at the time of measurement with respect to the film thickness of P1 at the time of no stub is obtained for each of the other stubs S2 to S6, the rate of change in the film thickness based on the influence of the stubs S2 to S6 (the position at the measurement of the film thickness) is also obtained. Therefore, by adding these amounts of change to the film thickness D₀1, it is possible to estimate the film thickness of P1 when the stubs S1 to S6 are set to certain positions. Accordingly, the film thicknesses of the specific positions P2 to P6 on the lines respectively passing through the stubs S2 to S6 other than the stub S1 can be estimated in the same manner. As a result, it is possible to estimate the arrangement of film thicknesses of P1 to P6 for any of combinations of the positions of the stubs S1 to S6. Since the number of selections of the positions that you can take for each of the stubs S1 to S6 is 19 as described above, assuming that no stub can also be selected, there are 20⁶ combinations of the position selection.

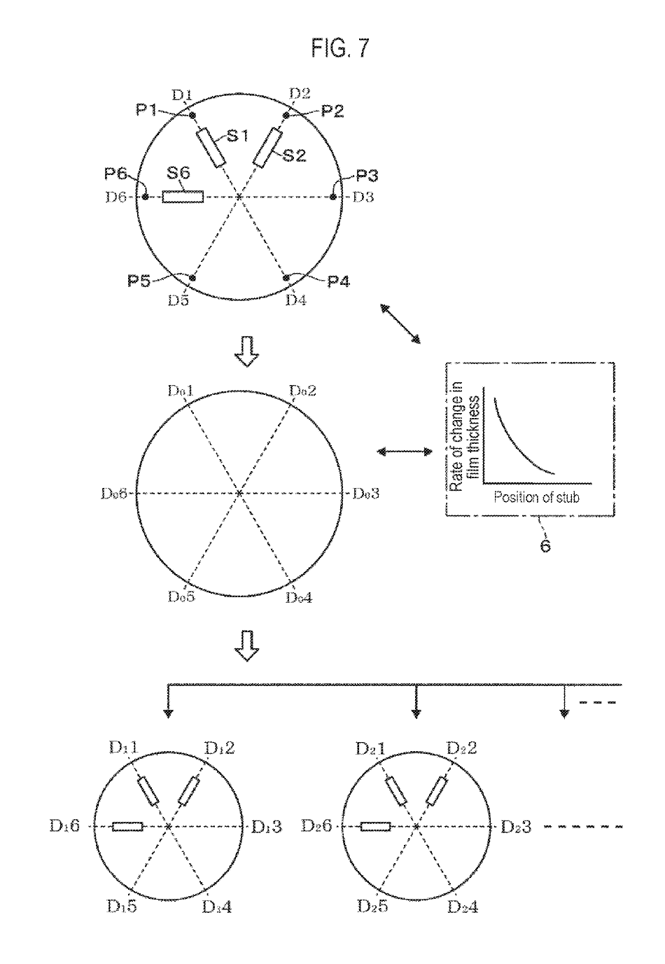

Meanwhile, the present inventors have found that the relationship between a change in the film thickness of P4, which is a position on the line passing through the stub S4 opposite the stub S1, and the position of the stub S1 is reverse to the relationship between P1 and the position of the stub S1. That is, since, regarding the change in the film thickness of P4, the stub S4 acts to cancel out the influence of the stub S1, the estimation of the film thickness of P4 can be achieved by the adjustment of the stub S1 instead of the adjustment of the stub S4, as apparent as will be described later. Therefore, the adjustment of the film thickness of each of P1 to P6 can be performed by using three consecutive stubs S located on one side, so to speak, without using all of the six stubs S1 to S6. As an example, as shown in FIG. 7, it is assumed that plasma treatment is performed on the wafer W using the stubs S6, S1 and S2 and that the film thickness at the positions of P1 to P6 are D1 to D6, respectively.

First, as described above, the film thicknesses D₀1 to D₀6 at the respective positions of P1 to P6 when the stubs S6, S1 and S2 are no stub state, are obtained. The state at this time is shown in FIG. 7. The film thickness D₀1 at P1 is obtained, for example, based on the data shown in FIGS. 11 and 13 as described above. Similarly, the film thicknesses D₀6 and D₀2 of P6 and P2 can also be obtained using the film thickness estimation data of P2 and P6 acquired in advance. The film thickness D₀4 of P4 can be obtained by using data obtained by reversing the sign of the vertical axis in the data shown in FIG. 11 used to obtain the film thickness D₀1 of P1. For example, if the stub S1 is a 2 mm stub, the film thickness D4 of P4 is assumed to be 994 Å. It can be seen from FIG. 11 that the rate of increase in the film thickness corresponding to the position of 2 mm of the stub S1 (the rate of increase in the film thickness with respect to the film thickness at no stub) is 0.6% (this value 0.6% may not be exact but is used for the sake of convenience). Therefore, the rate of increase in the film thickness at P4 on the line passing through the stub S4 opposite the stub S1 is —0.6% which is a reverse sign value of 0.6% which is the rate of increase in the film thickness of corresponding to the position of 2 mm of the stub S1. Since D4 is −0.6% with respect to D₀4, D₀4 is obtained as 1,000 Å.

Next, the film thickness is estimated in a case where the stub insertion has been changed. Here, as an example, estimation of film thicknesses of P1 to P6 at combinations of 2 mm, 3 mm and 4 mm stubs S6, S1 and S2 will be described. It is here assumed that the stubs S3 to S5 are in the state of no stub. The film thickness of P1 is calculated as D₀1+<amount of change in film thickness of P1 when the stub S1 is 3 mm (amount of change in film thickness with respect to the film thickness when the stub S1 is no stub)>+<amount of change in film thickness of P1 when the stub S6 is 2 mm (amount of change in film thickness with respect to the film thickness when the stub S6 is no stub)>+<amount of change in film thickness of P1 when the stub S2 is 4 mm (amount of change in film thickness with respect to the film thickness when the stub S2 is no stub)>.

Here, there may be a case where it is preferable to consider the influence of not only the stubs S positioned on both sides of a line at a specific position (for example, P1) (a line connecting the specific position and the center of the wafer W) but also stubs S of a second line positioned away from the specific position and a third line positioned away from the specific position, like antennas in which seven stubs can be inserted. In this case, film thickness estimation data defining the relationship between the rate of change in film thickness of the specific position and the positions of the stubs S corresponding to the two separate lines and film thickness estimation data defining the relationship between the rate of change in film thickness of the specific position and the positions of the stubs S corresponding to the three separate lines are also used. However, in a case of an apparatus capable of inserting six stubs, a place corresponding to a second line positioned away from the specific position is in an opposite relationship to a line of a stub adjacent to the specific position. Therefore, it is sufficient if estimation data up to the stub corresponding to both adjacent lines to the specific position are prepared.

On the other hand, the film thickness of P2 is calculated as D₀2+<amount of change in film thickness of P2 when the stub S2 is 4 mm (amount of change in film thickness with respect to the film thickness when the stub S2 is no stub)>+<amount of change in film thickness of P2 when the stub S1 is 3 mm (amount of change in film thickness with respect to the film thickness when the stub S1 is no stub)>+<amount of change in film thickness of P2 when the stub S6 is 2 mm (amount of change in film thickness with respect to the film thickness when the stub S6 is no stub)>. Regarding the rate of change of P2 when stub S6 is 2 mm, since P2 and P5 are an opposite relationship to each other, it is sufficient to use the reverse sign value of the amount of change of P5 when the 2 mm un stub S6 is used. This can be equally applied to calculation of estimation of the film thickness of P6.

Similarly, the estimation of the remaining P3 to P5 can be calculated as follows. The film thickness of P5 is calculated as D₀5+<amount of change in film thickness of P5 when the stub S6 is 2 mm (amount of change in film thickness with respect to the film thickness when the stub S6 is no stub)>+<amount of change in film thickness of P5 when the stub S1 is 3 mm (amount of change in film thickness with respect to the film thickness when the stub S1 is no stub)>+<amount of change in film thickness of P5 when the stub S2 is 4 mm (amount of change in film thickness with respect to the film thickness when the stub S2 is no stub)>. This can be equally applied to calculation of estimation of the film thickness of P3.

In addition, the film thickness of P4 is calculated as D₀4+<amount of change in film thickness of P4 when the stub S1 is 3 mm. (amount of change in film thickness with respect to the film thickness when the stub S1 is no stub)>+<amount of change in film thickness of P4 when the stub S6 is 2 mm (amount of change in film thickness with respect to the film thickness when the stub S6 is no stub)>+<amount of change in film thickness of P4 when the stub S2 is 4 mm (amount of change in film thickness with respect to the film thickness when the stub S2 is no stub)>.

As described above, it is possible to estimate the respective film thicknesses at P1 to P6 corresponding to all combinations of the positions of the stubs S6, S1 and S2. FIG. 7 schematically shows this state, in which the film thickness values of P1 to P6 in certain combinations of the positions of the stubs S6, S1 and S2 are D₁1 to D₁6, respectively and the film thickness values of P1 to P6 in other combinations of the positions of the stubs S6, S1 and S2 are D₂1 to D₂6, respectively. When 19 stubs with different lengths are prepared, so many 19³ cases are obtained even when stubs are only inserted in the positions of the stubs S6, S1 and S2.

For other combinations of three different consecutive stubs 5, that is, a combination of the stubs S1, S2 and S3, a combination of the stubs S2, S3 and S4, a combination of the stubs S3, S4 and S5, a combination of the stubs S4, S5 and S6, and a combination of the stubs S5, S6 and S1, the film thicknesses of P1 to P6 are estimated for each of the combinations of the positions of the stubs S) in the same manner. Therefore, since each stub S can be set in six types of combinations in different configurations, the number of combinations of three consecutively arranged stubs S is 19³×6 (when 19 stubs S of different lengths are prepared), assuming that setting of no stub for each of the three stubs S is excluded.

In addition, by excluding combinations in which stubs S having a strong effect on the film thickness are placed on both sides of stubs S having a weak effect on the film thickness, the number of combinations mentioned above is reduced. A stub S having a weak effect means setting a stub S in a position showing a small rate of change in film thickness in the data of FIG. 11, and a stub S having a high fleet means setting a stub S in a position showing a large rate of change in film thickness. Values of the rate of change corresponding to a strong effect and the rate of change corresponding to a weak effect are determined in advance.

When the arrangements of film thicknesses (combinations of film thicknesses) of P1 to P6 corresponding to the combinations of three consecutively arranged stubs S are provided in this way, proper combinations having good film thickness uniformity in the circumferential direction at positions distant by 145 mm from the center of the wafer W are selected from the combinations of film thicknesses. For example, 15 combinations are selected in order from a combination having the smallest difference between the maximum value and the minimum value among the film thicknesses of P1 to P6. The way of selecting combinations having good uniformity and the number of selections are not limited to this example.

It has been illustrated above that combinations of stubs S having good uniformity in the circumferential direction for the film thicknesses of P1 to P6 which are positions distant by, for example, 145 mm from the center of the wafer W are selected. However, in this embodiment, combinations of stubs S having good uniformity in the circumferential direction for the film thicknesses of Q1 to Q6 which are positions distant by, for example, 90 mm from the center of the wafer W are selected in the same manner. Q1 to Q6 are located on lines connecting P1 to P6 with the center of the wafer W, respectively. Even in this case, similarly, required film thickness estimation data is prepared, and 15 types of proper combinations having good film thickness uniformity in the circumferential direction at positions distant by 90 mm from the center of the wafer W are selected according to the same calculation and selection method.

So far, the explanation has been given to the method of selecting the positions of stubs S for promoting the circumferential uniformity of the film thicknesses of P1 to P6 and Q1 to Q6. However, in this embodiment, refractive indexes of P1 to P6 and Q1 to Q6 may be used to select the positions of stubs S for achieving the circumferential uniformity in the same manner. Since the refractive index is the refractive index of a formed film and is an index value of the electron density of plasma, like the film thickness. Further, the refractive index is introduced as an adjustment item in achieving the in-plane uniformity in the circumferential direction of plasma treatment. By using two indexes thus, it is possible to further improve the in-plane uniformity in the circumferential direction of plasma treatment.

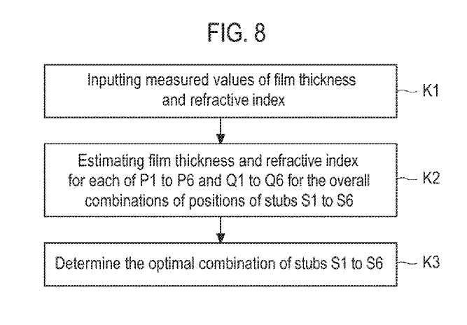

FIG. 8 outlines the above described steps. First, in step K1, stubs S are set o certain positions (an example of which will be described later), a film forming process by plasma is performed on the wafer W, the film thicknesses and the refractive indexes of P1 to P6 and Q1 to Q6 are measured, and measured values are input to a support apparatus to be described later. Next, in step K2, the film thicknesses and refractive indexes of P1 to P6 and Q1 to Q6 are estimated for all combinations of the stubs S1 to S6. Then, proper combinations of the stubs S1 to S6 are selected based on the estimated film thicknesses of P1 to P6 and Q1 to Q6 and the estimated refractive indexes of P1 to P6 and Q1 to Q6 (step K3).

An example of a method of selecting proper combinations in this case is as follows. For each of the combinations of the stubs S1 to S6, the Δ film thickness P which is a difference between the maximum value and the minimum value of the film thickness of P1 to P6 is obtained and the Δ film thickness Q which is a difference between the maximum value and the minimum value of the film thickness of Q1 to Q6 is obtained. Similarly, for the refractive index, the Δ refractive index P and the Δ refractive index Q are obtained. Further, combinations of stubs S1 to S6 in which each of these differences is included in the spec are firstly selected. Next, for each of the selected combinations, the Δ film thickness P, the Δ film thickness Q, the Δ refractive index P and the Δ refractive index Q which are the differences are respectively divided by predetermined normalization coefficients, and the smallest sum of the division values are treated as the optimal combination of the stubs S1 to S6. Note that a method of selecting the proper combinations of the stubs S1 to S6 in step K3 is not limited to the above method.

It has been illustrated in the above example that values of both film thickness and refractive index are used for each of P1 to P6 and Q1 to Q6. However, only one of the film thickness and the refractive index may be used (measured and estimated) to select the proper combinations of the stubs S1 to S6. In addition, as a position on the wafer W utilizing the film thickness value or the refractive index value, only the position of one group of a group of P1 to P6 and a group of Q1 to Q6 may be used. Further, the film thickness and the refractive index at positions of the dimensions other than the dimensions of P1 to P6 and Q1 to Q6 from the center of the wafer W may be used. Further, regarding setting the distance from the center to the position where an index value is to be obtained, the present disclosure is not limited the two kinds of distances (145 mm and 90 mm in the previous embodiment) but three or four or more may be used.

Further, although in this example the film thickness and the refractive index used to select the proper combinations of the stubs S1 to S6 are treated as index values corresponding to the electron density of plasma, an etching rate when etching a film. with an etchant or a transmittance or reflectance of the film may be used as an index value. Further, for example, when the plasma treatment is etching treatment, the index value may be an etching rate by an etching gas. Furthermore, the index value may be the electron density of plasma, in which case a probe may be used to measure the electron density of plasma

### [Description on Embodiment of Support Apparatus for Plasma Adjustment of the Present Disclosure]

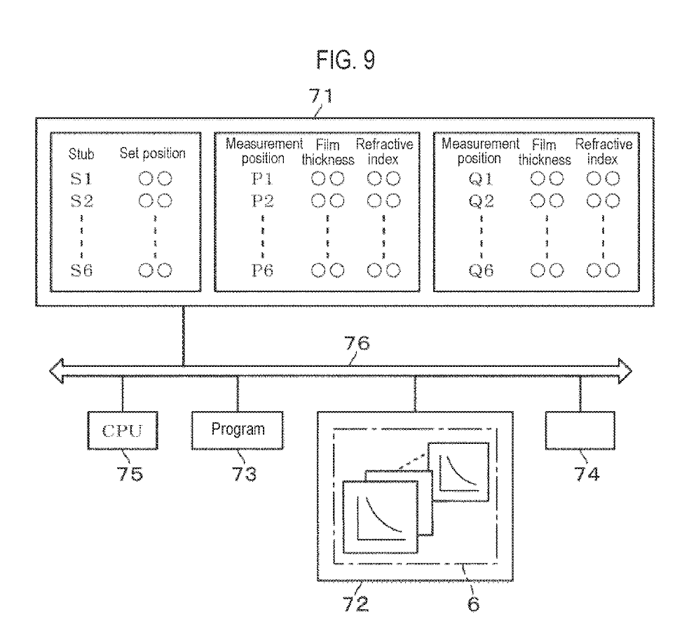

The above-described plasma adjustment method can be carried out by, for example, a support apparatus for plasma adjustment shown in FIG. 9. This support apparatus is implemented with a computer and includes an input part 71 having an input screen, a storage part 72 storing data 6 for estimating an index value (film thickness and refractive index in this example), a program storage part 73 storing a program including a step group for obtaining proper combinations of positions of the stubs S1 to S6 as described above from the combinations of the positions of the stubs S input to the input part 71 and the measured values of the film thickness and the refractive index, a storage part 74 storing a weighting coefficient for determining the weighting of the plasma processing apparatus for adjusting plasma, a CPU 75, and a bus 76.

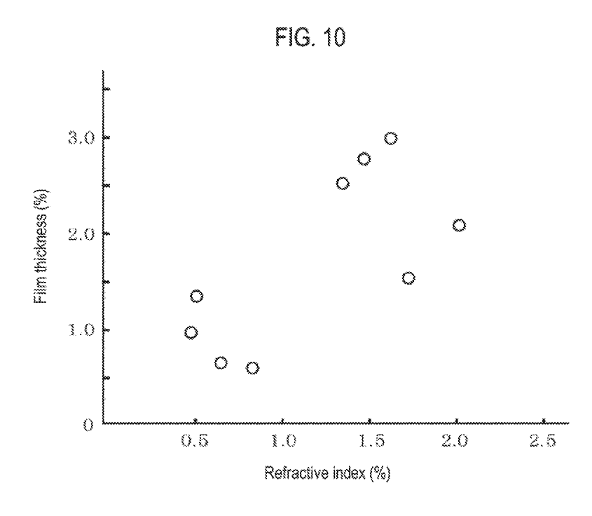

FIG. 10 shows results obtained from processes where three consecutive stubs S are set at various positions, a film forming process as plasma treatment is performed on the wafer W for each setting, the film thickness and the refractive index are measured at each of the positions of P1 to P6 and Q1 to Q6, and the uniformity of each of the film thickness and the refractive index is obtained from the result of the measurement. For example, in the case of P1 to P6, the “uniformity” is calculated as a value obtained by dividing the difference between the maximum value and the minimum value of the film thicknesses of P1 to P6 by the average value of the film thickness [{(maximum value−minimum value)/average value}×100%].

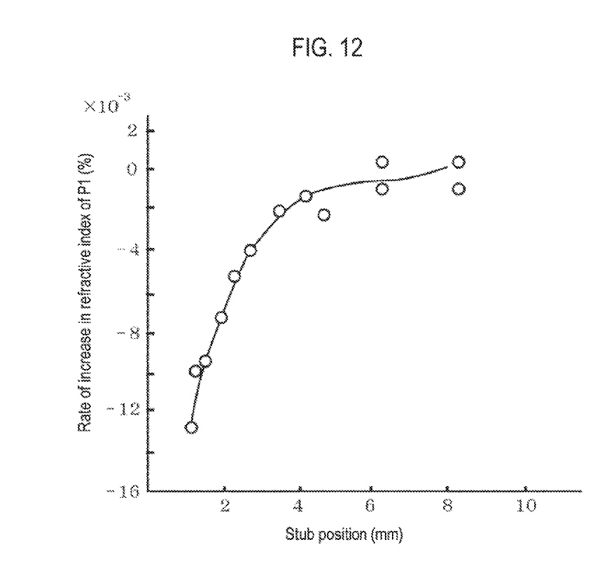

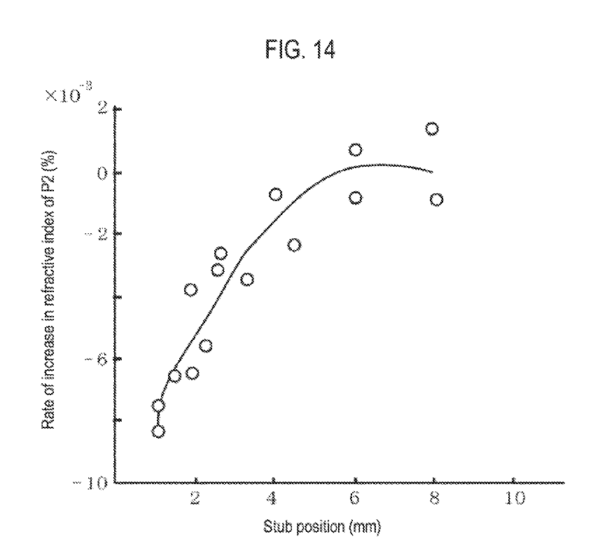

Estimation data of the film thickness or the refractive index is created based on the measurement result. As an example of the estimation data, FIG. 11 shows a rate of increase of film thickness of P1 when the position of the stub S1 is set to the film thickness of P1 when the stub S1 is no stub. FIG. 12 shows the relationship between the set position of the stub S1 and the rate of increase of the refractive index of P1 and FIGS. 13 and 14 respectively show the relationship between the set position of the stub S1 and the rate of increase in film thickness of P2 and the relationship between the set position of the stub S1 and the rate of increase in refractive index of P2.

The estimation data 6 are prepared for not only the relationship between the stub S and the film thickness and refractive index on the line passing through the stub S (for example, the relationship shown in FIGS. 11 and 12) as described above but also the relationship between the stub S and the film thickness and refractive index on a line adjacent to the line passing through the stub S (for example, the relationship shown in FIGS. 13 and 14) and the relationship between the stub S and the film thickness and refractive index on two lines adjacent to the line passing through the stub S.

Further, since it is difficult to completely eliminate the performance difference between apparatuses, the plasma processing apparatus is assigned with a weighting coefficient corresponding to the plasma processing apparatus. The weighting coefficient refers to a coefficient assigned to the rate of increase of the film thickness according to the position of the stub S which is read from the estimation data and is determined from a previous measurement result for each plasma processing apparatus. Therefore, the plasma processing apparatus and the weighting coefficient are associated with each other in the storage part 74, and the weighting coefficient for the plasma processing apparatus for adjusting plasma is read from the storage part 74.

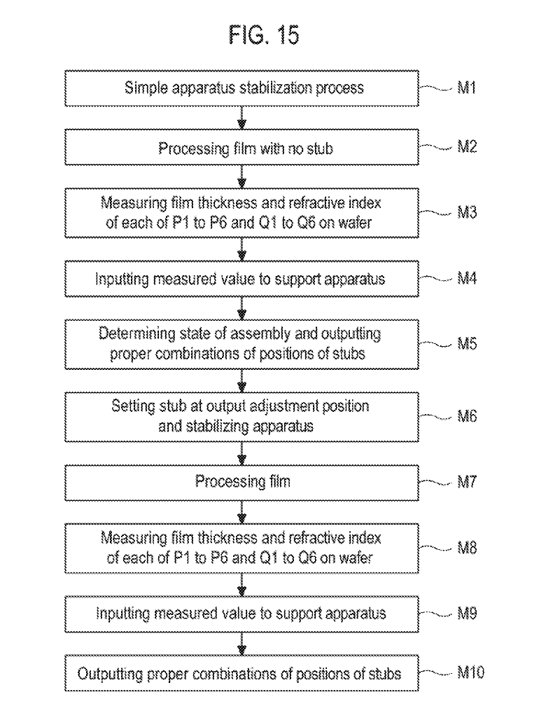

Next, the operation of actually adjusting the plasma of the plasma processing apparatus using the plasma adjustment support apparatus shown in FIG. 9 will be described with reference to FIG. 15. For example, after maintenance is completed and the plasma processing apparatus is assembled, a simple apparatus stabilization process (so-called conditioning) is performed (step M1). This process is to remove moisture and metal components from a processing container by generating plasma by a predetermined gas. Next, with the stubs S1 to S6 put in the state of no stub, a thin film is formed by plasma treatment on the wafer W (step M2), and the film thicknesses and refractive indexes of P1 to P6 and Q1 to Q6 on the wafer W are measured (step M3). Then, the measured values of these film thicknesses and refractive indices are input through the input part 71 of the support apparatus (step M4), and it is determined by the program whether or not the assembled state of the apparatus is appropriate (step M5).

In the step M5, the film thicknesses and refractive indexes of the respective positions (P1 to P6 and Q1 to Q6) for each of the combinations of positions of the stubs S as described above are obtained based on the measured values. If it is determined from the results of the film thicknesses and refractive indexes that the in-plane uniformity in the circumferential direction of these values cannot be secured by the adjustment of the stubs S, an output as being unadjustable is made. In this case, for example, the apparatus is re-assembled. A specific example of the kind of determination method may be a case where the difference between the maximum and the minimum in the circumferential direction does not satisfy all of the specs.

When the assembling is properly performed, a proper combination of positions of the stubs S is selected using the estimation data 6 as described above and is outputted. Then, a combination of the positions of the stubs S is set based on the selected combination, and a stabilization process finer than the apparatus stabilization process performed in the step M1, example, a stabilization process having a long process item or a long processing time, is performed (step M6). Next, plasma treatment is performed on the wafer W to form a thin film (step M7), and the film thicknesses and refractive indexes of P1 to P6 and Q1 to Q6 on the wafer W are measured (step M8). Then, measured values of the film thicknesses and refractive indexes are input through the input part 71 of the support apparatus (step M9), and a proper combination of the positions of the stubs S is selected and outputted. in addition, in this example, three consecutively arranged stubs S are used for the six mounting holes 52. When the optimal position of the stubs S thus obtained is determined, plasma treatment is performed on a product wafer with this setting.

Although in this example the three consecutive arranged stubs S are used, the present disclosure is not limited to this, but six stubs S may be used, for example. Although in the above example six stubs S are used, that is, the stubs S are mounted at six positions, they may be mounted at seven, eight or more, or three to five positions at equal intervals in the circumferential direction.

A position for measuring or estimating the film thickness or the refractive index is not limited to being set on a line connecting a stub S and the center of the wafer W For example, even a position deviated from the line can be applied as long as the relation between the film thickness and the position of the stub S can be obtained.

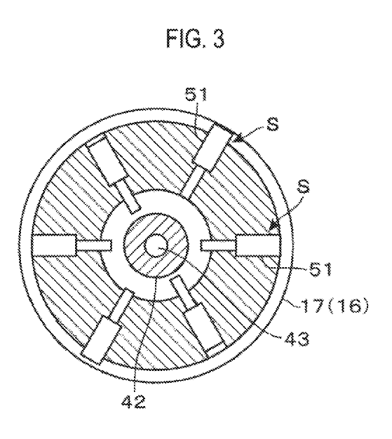

Further, the stub which is the adjustment part used in the present disclosure is not limited to the structure shown in FIGS. 1 to 3 but may be applied to adjust plasma by adjusting the length of a vertical waveguide located above the peripheral portion of the wafer W by means of a movable part, as disclosed in, for example, Japanese Patent Application Laid-Open No. 2010-232493.

According to the present disclosure in some embodiments, in a microwave plasma processing apparatus in which a plurality of adjustment parts for adjusting an electric field distribution of a microwaves is installed along the circumferential direction of the processing container (the circumferential direction of the substrate), estimation data to know haw much the index value corresponding to the electron density of plasma at a specific position increases or decreases when a certain adjustment part is located at a certain adjustment position is acquired beforehand. Then, plasma is actually generated, an index value is measured at a specific position, and a data processing part obtains correspondence data between various combinations of adjustment parts and adjustment positions and a plurality of index values in the circumferential direction of the substrate based on the combinations of the adjustment parts and the adjustment positions at the time of measurement and the estimation data. Based on this correspondence data, proper combinations of adjustment parts and adjustment positions are derived. Therefore, it is possible to easily obtain proper combinations of adjustment parts and adjustment positions which can provide good uniformity of the electron density of plasma in the circumferential direction and hence to reduce the burden on a worker for adjusting the plasma, and reduce the burden of education for the worker.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A support apparatus for plasma adjustment, which is used in a plasma processing apparatus in which a processing gas is plasmarized by a microwave propagated from a coaxial waveguide located above a central portion of a substrate placed in a processing container into the processing container via a flat slot antenna and a dielectric plate, plasma treatment is performed on the substrate, and a plurality of adjustment parts for adjusting an electric field distribution of the microwave installed along a circumferential direction of the processing container, comprising:
a storage part that stores index value estimation data including data defining an amount of change in an index value between adjustment positions for each of the adjustment parts, the index value corresponding to electron density of plasma at a plurality of specific positions separated by a predetermined distance from a central axis of the coaxial waveguide and located along the circumferential direction when viewed from the top;
an input part for inputting a measurement result of the index value obtained when the plasma is generated and the adjustment positions of the adjustment parts; and
a data processing part configured to estimate the index value for each of adjustment positions of the adjustment parts based on input items input to the input part and the estimation data and configured to select proper combinations of the adjustment positions of the adjustment parts based on combinations of the adjustment positions of the adjustment parts and estimated values of a plurality of index values in the circumferential direction corresponding to the respective combinations.

2. The support apparatus of claim 1, wherein the specific position is located on a line extending from the central axis of the coaxial waveguide toward each of the plurality of adjustment parts when viewed from the top, and
wherein the estimation data includes the amount of change in the index value on the line and the amount of change in the index value on an adjacent line for the index value at the specific position between the adjustment positions of each of the adjustment parts arranged on the line.

3. The support apparatus of claim 1, wherein the index value corresponding to plasma density is a value selected from the electron density of plasma and a characteristic value of a film of the substrate after the plasma treatment.

4. The support apparatus of claim 1, wherein the estimation data are data defining the relationship between the adjustment positions of the adjustment parts and the amount of change in the index value when the adjustment parts are set to the adjustment positions with respect to the index value when the adjustment parts are set to reference adjustment positions.

5. The support apparatus of claim 1, wherein the data processing part selects the proper combinations based on one index value, selects the proper combinations based on an index value different from the one index value, and selects an optimal combination based on the selected proper combinations.

6. The support apparatus of claim 1, wherein a plurality of specific positions having different distances are set as the specific positions which are distant by a predetermined distance from the central axis of the coaxial waveguide,
wherein the estimation data are prepared according to each of the plurality of specific positions, and
wherein the data processing part is configured to select proper combinations of the adjustment positions of the adjustment parts for each of the specific positions based on the measurement result of the index value at each of the plurality of specific positions input to the input part and the estimation data prepared according to each of the plurality of specific positions and is configured to select the optimal combination of the adjustment portions of the adjustment parts from the selected proper combinations of the adjustment positions of the adjustment parts for each of the specific positions.

7. The support apparatus of claim 1, wherein the estimation data for each plasma processing apparatus are weighted.

8. A method for adjusting plasma of a plasma processing apparatus in which a processing gas is plasmarized by a microwave propagated from a coaxial waveguide located above a central portion of a substrate placed in a processing container into the processing container via a flat slot antenna and a dielectric plate, plasma treatment is performed on the substrate, and a plurality of adjustment parts for adjusting an electric field distribution of the microwave installed along a circumferential direction of the processing container, comprising:
generating plasma using the plasma processing apparatus and measuring an index value corresponding to electron density of plasma at a plurality of specific positions separated by a predetermined distance from a central axis of the coaxial waveguide and located along the circumferential direction;
inputting a measurement result of the index value and adjustment positions of the adjustment parts to an input part;
reading index value estimation data defining an amount of change in the index value between the adjustment positions of the adjustment parts for each of the adjustment parts from a storage part; and
subsequently, estimating the index value for each of the adjustment positions of the adjustment parts based on the read estimation data and input items input to the input part and selecting proper combinations of the adjustment positions of the adjustment parts based on combinations of the adjustment positions of the adjustment parts and the estimated values of the plurality of index values in the circumferential direction corresponding to the respective combinations.

9. The method of claim 8, wherein the specific position is located on a line extending from the central axis of the coaxial waveguide toward each of the plurality of adjustment parts when viewed from the top, and
wherein the estimation data include the amount of change in the index value on the line and the amount of change in the index value on an adjacent line for the index value at the specific position between the adjustment positions of each of the adjustment parts arranged on the line.

10. method of claim 8, further comprising:
performing a first stabilizing process for stabilizing an interior of the processing container, performing plasma treatment on the substrate using the plasma processing apparatus, selecting proper combinations of the adjustment positions of the adjustment parts based on a result of the performed plasma treatment, and performing a second stabilization process for increasing a degree of stabilization of the interior of the processing container over the first stabilization process by adopting the selected proper combinations; and
subsequently, selecting proper combinations of the adjustment positions of the adjustment parts to be used to process the substrate according to the process of claim 8.

11. A non-transitory computer-readable storage medium storing software used for the support apparatus for plasma adjustment of claim 1, wherein the software is configured to execute a function of the data processing part.
